(19) United States
(12) Patent Application Publication
(10) Pub. No.: US 2013/0001525 A1
(43) Pub. Date: Jan. 3, 2013

(54) THIN FILM TRANSISTOR AND PRESS SENSING DEVICE USING THE SAME

(75) Inventors: CHUN-HUA HU, Beijing (CN); CHANG-HONG LIU, Beijing (CN); SHOU-SHAN FAN, Beijing (CN)

(73) Assignees: HON HAI PRECISION INDUSTRY CO., LTD., Tu-Cheng (TW); TSINGHUA UNIVERSITY, Beijing (CN)

(21) Appl. No.: 13/323,830

(22) Filed: Dec. 13, 2011

(30) Foreign Application Priority Data
Jun. 30, 2011 (CN) 201110181458.8

(51) Int. Cl. H01L 51/30

(52) U.S. Cl. 257/40; 257/E51.025

(57) ABSTRACT

A thin film transistor controlled by a pressure includes a source electrode, a drain electrode, a semiconductor layer, a gate electrode, and an insulative layer. The drain electrode is spaced from the source electrode. The semiconductor layer includes a polymer composite layer and is electrically connected with the source electrode and the drain electrode. The polymer composite includes a polymer substrate and a plurality of carbon nanotubes dispersed in the polymer substrate. An elastic modulus of the polymer substrate is ranged from about 0.1 MPa to about 10 MPa. The gate electrode is electrically insulated from the source electrode, the drain electrode, and the semiconductor layer by the insulative layer. A press sensing device using the above-mentioned thin film transistor is also provided.

### RELATED APPLICATIONS

This application claims all benefits accruing under 35 U.S.C. §119 from China Patent Application No. 201110181458.8, filed on Jun. 30, 2011 in the China Intellectual Property Office, the disclosure of which is incorporated herein by reference.

### BACKGROUND

1. Technical Field

The present disclosure relates to a thin film transistor and a press sensing device using the same.

2. Discussion of Related Art

A typical thin film transistor (TFT) mainly includes a substrate, a gate electrode, an insulative layer, a drain electrode, a source electrode, and a semiconductor layer. The gate electrode is insulated from the semiconductor layer by the insulative layer. The source electrode and the drain electrode are insulated from each other. The source electrode and the drain electrode are both electrically connected to the semiconductor layer. The source electrode, the drain electrode, and the gate electrode are made of electrically conductive material. The conductive material is usually a metal or an alloy. When a pressure is applied on the gate electrode, the semiconductor layer can generate a number of carriers. When the number of carriers reaches a certain level, the source electrode and the drain electrode forms a conductive pathway thereby generating a current flowing from the source electrode to the drain electrode. However, parameters of the thin film transistor (e.g. current between the source electrode and the gate electrode, the gate electrode capacitance, etc) are fixed values and cannot be adjusted, which limits the applications of the thin film transistors.

What is needed, therefore, is to provide a thin film transistor and a press sensing device using the same, which can overcome the shortages discussed above.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a cut-away view of one embodiment of a thin film transistor including a semiconductor layer, a source gate and a drain gate.

FIG. 2 is a cut-away view of the semiconductor layer used in the thin film transistor shown in FIG. 1.

FIG. 3 is a schematic view of the thin film transistor in working status shown in FIG. 1.

FIG. 4 shows a relationship graph of current-voltage between the source gate and the drain gate shown in FIG. 1.

FIG. 5 is cut-away view of another embodiment of a thin film transistor.

FIG. 6 is cut-away view of one embodiment of a press sensing device.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

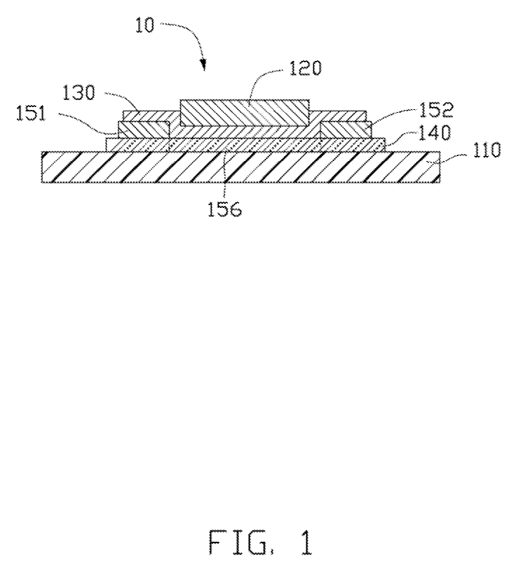

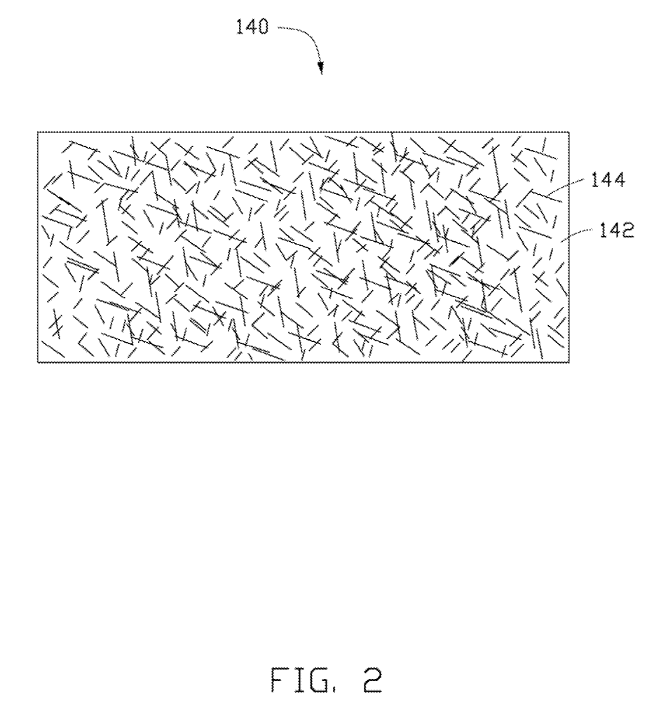

Referring to FIG. 1 and FIG. 2, one embodiment of a thin film transistor 10 is provided. The thin film transistor 10 can normally work through a pressure applied on the thin film transistor 10. The thin film transistor 10 has a top gate structure and includes a gate electrode 120, an insulative layer 130, a semiconductor layer 140, a source electrode 151 and a drain electrode 152. The thin film transistor 10 can be located on an insulative board 110.

The semiconductor layer 140 is located on the insulative board 110. The source electrode 151 and the drain electrode 152 are spaced from each other and electrically connected to the semiconductor layer 140. The insulative layer 130 is located between the semiconductor layer 140 and the gate electrode 120. The insulative layer 130 is located between the gate electrode 120 and a surface of the semiconductor layer 140. The gate electrode 120 is insulated from the semiconductor layer 140, the source electrode 151 and the drain electrode 152 by the insulative layer 130. A channel 156 is defined in the semiconductor layer 140 between the source electrode 151 and the drain electrode 152. In one embodiment, the gate electrode 120 is located on a surface of the insulative layer 130 corresponding to the channel 156.

The source electrode 151 and the drain electrode 152 can be located on the semiconductor layer 140 or on the insulative board 110. More specifically, the source electrode 151 and the drain electrode 152 can be located on a top surface of the semiconductor layer 140, and at the same side of the semiconductor layer 140 as the gate electrode 120. In other embodiments, the source electrode 151 and the drain electrode 152 can be located on the insulative board 110 and covered by the semiconductor layer 140. The source electrode 151 and the drain electrode 152 are at a different side of the semiconductor layer 140 from the gate electrode 120. In other embodiments, the source electrode 151 and the drain electrode 152 can be formed on the insulative board 110, and located on a same surface of the semiconductor layer 140.

The insulative board 110 is configured to support the thin film transistor 10. A material of the insulative board 110 can be silicon, silicon dioxide, glass, ceramic, diamond, or other inorganic material. The material of the insulative board 110 can also be plastic material, resin or other polymer material. In one embodiment, the material of the insulative board 110 is silicon. A plurality of the thin film transistors 10 can be located on the insulative board 110 to form a thin film transistor panel or other thin film transistor semiconductor devices.

The semiconductor layer 140 is a flexible polymer composite layer. The polymer composite layer includes a polymer substrate 142 and a number of carbon nanotubes 144 dispersed in the polymer substrate 142. An elastic modulus of the polymer substrate 142 can be in a range from about 0.1 megapascal (MPa) to about 10 MPa, for example 1 MPa, 3 MPa, 5 MPa or 8 MPa. Therefore, the semiconductor layer 140 has good elasticity. The polymer substrate 142 can be polydimethylsiloxane (PDMS), polyurethane (PU), polyacrylate, polyester, styrene-butadiene rubber, fluorine rubber, or silicone rubber. In one embodiment, the polymer substrate 142 is a polydimethylsiloxane (PDMS) layer, the elastic modulus of which is about 500 kilo pascals (KPa).

A weight percentage of the carbon nanotubes 144 in the polymer composite layer is in a range from about 0.1% to about 1%. In one embodiment, the weight percentage of the carbon nanotubes 144 is about 0.5% in the semiconductor layer 140. The carbon nanotubes 144 can be single-walled carbon nanotubes, double-walled carbon nanotubes, or combination thereof. A diameter of the single-walled carbon nanotubes is in the approximate range from 0.5 nanometers (nm) to 50 nm. A diameter of the double-walled carbon nanotubes is in the approximate range from 1.0 nm to 50 nm. In one embodiment, the carbon nanotubes 144 are semi-conductive carbon nanotubes.

A length of the semiconductor layer 140 can be in an approximate range from 1 micrometer (μm) to 100 μm. A width of the semiconductor layer 140 can be in an approximate range from 1 μm to 1 millimeter (mm) A thickness of the semiconductor layer 140 can be in a range from about 0.5 nm to about 100 μm. A length of the channel 156 can be in an approximate range from 1 μm to 100 μm. A width of the channel 156 can be in an approximate range from 1 μm to 1 mm. In one embodiment, the length of the semiconductor layer 140 is about 50 μm, the width of the semiconductor layer is about 300 μm, the thickness of the semiconductor layer 140 is about 1 μm, the length of the channel 156 is about 40 μm, and the width of the channel 156 is about 300 μm.

A material of the source electrode 151, the drain electrode 152, and the gate electrode 120 is a conductor, and can be pure metals, metal alloys, indium tin oxide (ITO), antimony tin oxide (ATO), silver paste, conductive polymer, metallic carbon nanotubes, or carbon nanotube metal composite. The pure metals can be aluminum, copper, tungsten, molybdenum, gold, cesium, or palladium. The metal alloy can be any alloy of aluminum, copper, tungsten, molybdenum, gold, cesium, or palladium. A thickness of the source electrode 151, the drain electrode 152, and the gate electrode 120 is about 0.5 nm to 100 μm. A distance between the source electrode 151 and the drain electrode 152 is about 1 to 100 μm. In one embodiment, the materials of the source electrode 151, the drain electrode 152, and the gate electrode 120 are pure palladium films, and the thickness of the source electrode 151, the drain electrode 152, and the gate electrode 120 are all about 5 nm.

In one embodiment, the semiconductor layer 140 is a carbon nanotube layer composed of a number of carbon nanotube films, and the carbon nanotubes in the carbon nanotube layer substantially extend along a same direction. The source electrode 151 and the drain electrode 152 are separately arranged along the extending direction of the carbon nanotubes in the carbon nanotube layer.

According to the manufacturing process of the thin film transistor 10, the insulative layer 130 can completely or partly cover the semiconductor layer 140, the source electrode 151, and the drain electrode 152, to ensure the semiconductor layer 140 is electrically insulated from the gate electrode 120, and the gate electrode 120 is electrically insulated from the source electrode 151 and the drain electrode 152. In one embodiment, the source electrode 151 and the drain electrode 152 are located on the top surface of the semiconductor layer 140, and the insulative layer 130 is located between the source electrode 151 and the drain electrode 152. The insulative layer 130 covers the semiconductor layer 140.

A material of the insulative layer 130 can be a rigid material such as silicon nitride (Si₃N₄) or silicon dioxide (SiO₂), or a flexible material such as polyethylene terephthalate (PET), benzocyclobutenes (BCB), or acrylic resins. A thickness of the insulating layer 130 can be in an approximate range from 0.1 nm to 10 μm. In one embodiment, the thickness of the insulative layer 130 ranges from about 50 nm to about 1 μm. In another embodiment, the thickness of the insulative layer 130 is about 500 nm.

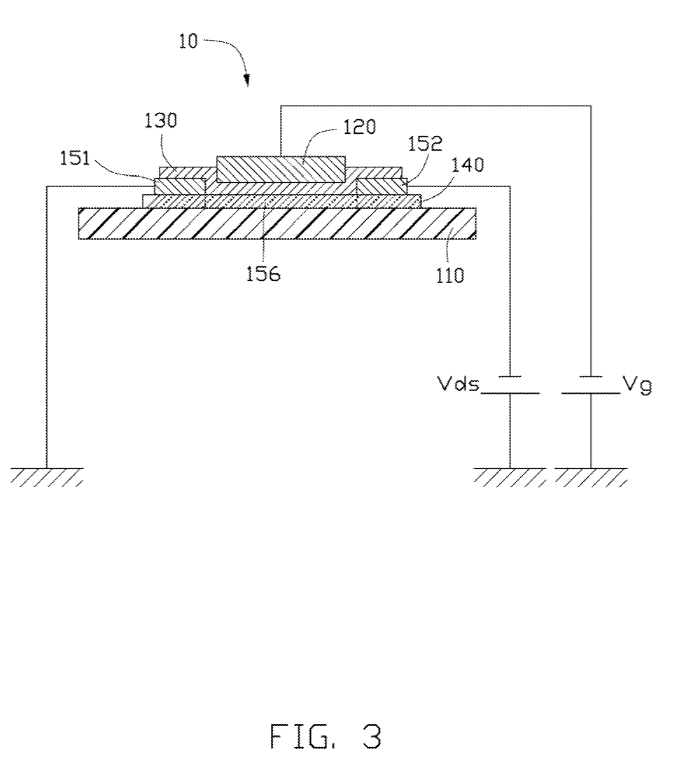

Referring to FIG. 3, when the thin film transistor 10 is in use, the source electrode 151 is grounded, a voltage V_{g} is applied on the gate electrode 120, and a voltage V_{ds} is applied on the drain electrode 152. An electric field is formed in the channel 156 of the semiconductor layer 140 by the voltage V_{g}. Accordingly, carriers are generated in the channel 156 near the gate electrode 120. When the V_{g} reaches a threshold voltage between the source electrode 151 and the drain electrode 152, an electrical pathway is formed in the channel 156. A current will then flow through the channel 156 from the source electrode 151 to the drain electrode 152. The source electrode 151 and the drain electrode 152 are electrically connected to each other, the thin film transistor 10 is in working status. When on pressure is applied on the thin film transistor 10, or the thin film transistor 10 is in a working status, the semiconductor layer 140 is a electrical conductor, rather than a semiconductor.

If the thin film transistor 10 is in a working status, and a pressure is perpendicularly and uniformly applied on the gate electrode 120, the pressure can also be perpendicularly and uniformly applied on the semiconductor layer 140. Because the semiconductor layer 140 has good elasticity, the shape of the semiconductor layer 140 can be changed, and accordingly, the shapes of the carbon nanotubes 144 in the semiconductor layer 140 changes. Thus, band gaps of the carbon nanotubes 144 increase, and band gaps of the semiconductor layer 140 also increase. That is, the semi-conductive properties of the semiconductor layer 140 improve, which makes a switching ratio of the semiconductor layer 140 improve gradually.

In one embodiment, the semiconductor layer 140 is a P-type semiconductor. When no pressure is applied on the thin film transistor 10, a positive voltage is applied on the gate electrode 120, a current I_{DS} between the source electrode 151 and the drain electrode 152 can be turned off. If the semiconductor layer 140 is a P-type semiconductor and a negative voltage is applied on the gate electrode, the current I_{DS} between the source electrode 151 and the drain electrode 152 cannot be turned off, and the current I_{DS} can still flow between the source electrode 151 and the drain electrode 152. In this embodiment, the semiconductor layer 140 is a P-type semiconductor because the carbon nanotubes 144 in the polymer substrate 142 are pure carbon nanotubes, which can absorb oxygen gas to display P-type.

In another embodiment, the semiconductor layer 140 is an N-type semiconductor. When the negative voltage is applied on the gate electrode, the current I_{DS} between the source electrode 151 and the drain electrode 152 can be turned off. If the semiconductor layer 140 is an N-type semiconductor and the positive voltage is applied on the gate electrode, the current I_{DS} between the source electrode 151 and the drain electrode 152 cannot be turned off, and the current I_{DS} can still flow between the source electrode 151 and the drain electrode 152. In this embodiment, the semiconductor layer 140 is the N-type semiconductor, because the carbon nanotubes 144 in the polymer substrate 142 are chemically doped to display N-type. In one embodiment, the N-type semiconductor layer 140 is formed by soaking the carbon nanotubes 144 with a polythyleneimine solution before dispersing the soaked carbon nanotubes 144 in the polymer substrate 142.

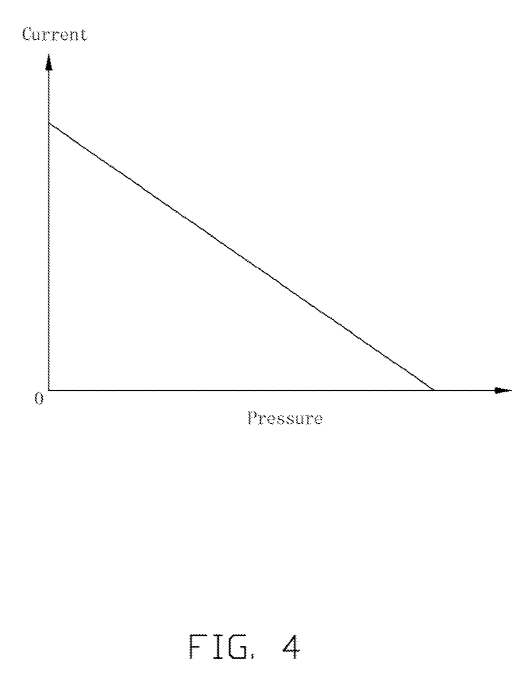

In use of the thin film transistor 10, if the semiconductor layer 140 is the P-type semiconductor and the positive voltage is applied on the gate electrode 130, or the semiconductor layer 140 is the N-type semiconductor and the negative voltage is applied on the gate electrode 130, the current I_{DS} between the source electrode 151 and the drain electrode 152 changes along with the pressure applied on the thin film transistor 10. If the pressure increases gradually from about 10⁵ pascals (Pa) to about 10⁷ Pa, the current I_{DS} will gradually decrease to 0, that is, the current I_{DS} has an inverse relationship with the pressure, as shown in FIG. 4. Thus, the current I_{DS} can be cut off by the pressure applied on the thin film transistor 10. The thin film transistor 10 can be widely used in electronic field.

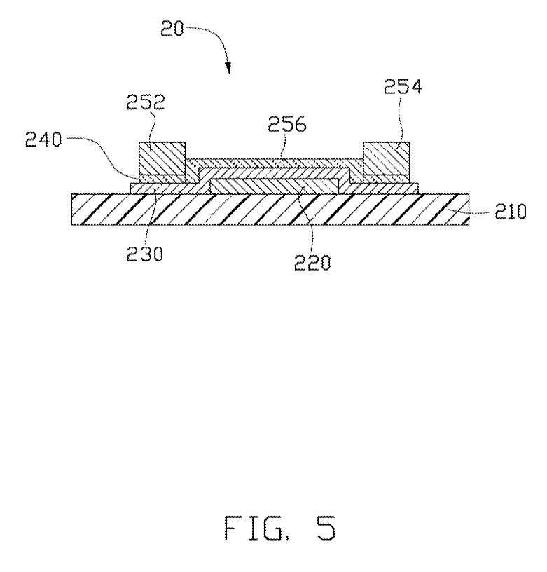

Referring to FIG. 5, one embodiment of a thin film transistor 20 controlled by pressure is provided. The thin film transistor 20 has a bottom gate structure and includes a gate electrode 220, an insulative layer 230, a semiconductor layer 240, a source electrode 251 and a drain electrode 252. The thin film transistor 20 is located on an insulative board 210. The insulative layer 230 is a polymer layer. A channel 256 is defined in the semiconductor layer 240 and located between the source electrode 251 and the drain electrode 252.

The structure of the thin film transistor 20 is similar to that of the thin film transistor 10 except that the gate electrode 220 is located on the insulative board 210. The insulative layer 230 covers the gate electrode 220. The semiconductor layer 240 is located on the insulative layer 230, and insulated from the gate electrode 220 by the insulative layer 230. Thus, when the thin film transistor 20 is in use, the pressure is directly applied on the semiconductor layer 240 rather than on the insulative layer 230.

Other characteristics of the thin film transistor 20 are the same as those of the thin film transistor 10 discussed above.

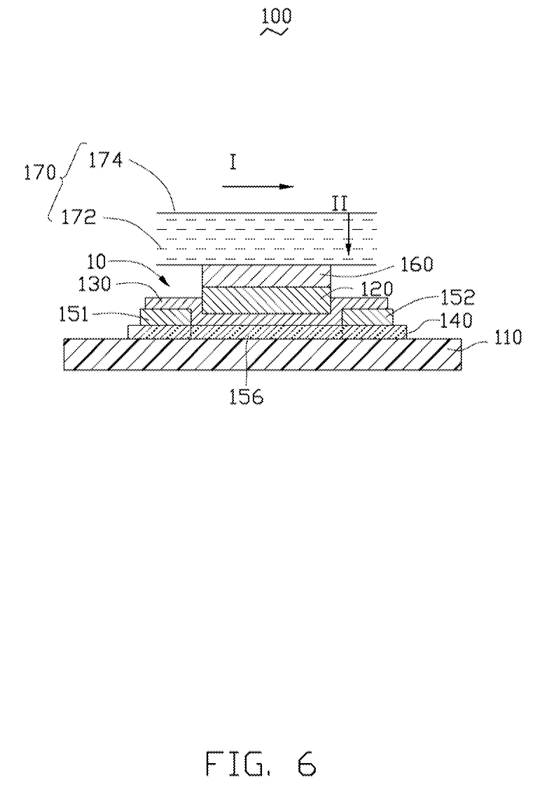

Referring to FIG. 6, one embodiment of a press sensing device 100 is provided. The press sensing device 100 includes a press producing unit 170 and the thin film transistor 10. The press producing unit 170 applies a perpendicular pressure on the thin film transistor 10. Specifically, the press producing unit 170 applies the pressure on the insulative layer 130 in the thin film transistor 10.

The press producing unit 170 can generate pressure by solid, gas, or liquid. The pressure produced by the solid can be a pressure from a finger or heavy materials. The pressure produced by the gas can be generated by changing the gas pressure. The pressure produced by the liquid can be formed by liquid flowing or the weight of the liquid. Therefore, the press sensing device 100 can be a water tower, an automatic control system of gas pressure or water level in a boiler.

In one embodiment, the press producing unit 170 includes a liquid 172 and a passage 174 receiving the liquid 172. The liquid 172 contacts an inner side wall of the passage 174. The thin film transistor 10 is located on an outer surface of the passage 174. The liquid 172 can flow in the passage 174 along the direction I shown in FIG. 7. The liquid 172 applies a pressure P on the thin film transistor 10 along the direction II shown in FIG. 7. A material of the passage 174 can be a polymer material such as polyethylene, polypropylene, or a metal such as steel. Because the current I_{DS} between the source electrode 151 and drain electrode 152 is related to the pressure produced by the liquid 172, therefore the pressure P produced by the liquid 172 can be calculated by the current I_{DS}. The pressure P and the flowing speed v of the liquid 172 can satisfy the following relationship:

$$P + ρ gh + \frac{1}{2} ρ {v}^{2} = Const$$

wherein, ρ is the density of the liquid 172, g is gravity acceleration, and h is the depth of the liquid 172 in the passage 174 along the II direction, Const is a constant value. Therefore, the flowing speed v of the liquid 172 can be determined according to the pressure P of the liquid 172, and determined in terms of the current I_{DS}.

The thin film transistor 10 and the press producing unit 170 should be electrically insulated from each other. Therefore, the press sensing device 100 can further include a packaged layer 160 located between the outer surface of the passage 174 and the gate electrode 120 in the thin film transistor 10. The packaged layer 160 is made of flexible and electrically insulative materials, such as resin or insulative plastics. In one embodiment, the packaged layer 160 is made of insulative plastic, and the thickness of the packaged layer 160 is about 200 nm.

In one embodiment, the thin film transistor 10 is completely enveloped by the packaged layer 160. The thin film transistor 10 can be located on the inner surface of the passage 174, and the insulative board 110 in the thin film transistor 10 is attached to the inner surface of the passage 174. The thin film transistor 10 is electrically insulated from the liquid 172 by the packaged layer 160.

The thin film transistor 10 can further includes a pressed element. The pressure generated by the press producing unit 140 is directly applied on the pressed element, and then the pressure is applied on the insulative layer 130 in the thin film transistor 10 by the pressed element.

The press sensing device 100 can further includes a sensing date unit connected with the thin film transistor 10. The sensing date unit displays signals converted from current changes caused by the pressure applied on the thin film transistor 10.

It can be understood that the thin film transistor 20 can instead of the thin film transistor 10 be used in the press sensing device 100.

According to the above descriptions, the thin film transistors controlled by the pressure of the present disclosure have the following advantages. Firstly, the structure of the thin film transistors is simple and the thickness of the thin film transistors is thin. Secondly, the current I_{DS} between the source electrodes and drain electrodes in the thin film transistors changes along with the pressure applied on the semiconductor layers, such that the thin film transistors can be adjusted by the pressure, and the thin film transistors can be applied in medical devices, regulators, keystroke of electronic devices, flow automatic controllers, and industrial control and monitor devices. Thirdly, the thin film transistors are simple and low cost, making it suitable for large scale manufacturing.

It is to be understood that the above-described embodiment is intended to illustrate rather than limit the disclosure. Variations may be made to the embodiment without departing from the spirit of the disclosure as claimed. The above-described embodiments are intended to illustrate the scope of the disclosure and not restricted to the scope of the disclosure.

What is claimed is:

1. A thin film transistor, comprising:
a source electrode;
a drain electrode spaced from the source electrode;
a semiconductor layer comprising a polymer composite layer electrically connected with the source electrode and the drain electrode, the polymer composite layer comprising a polymer substrate and a plurality of carbon nanotubes dispersed in the polymer substrate, an elastic modulus of the polymer substrate ranging from about 0.1 MPa to about 10 MPa;
an insulative layer; and
a gate electrode electrically insulated from the source electrode, the drain electrode, and the semiconductor layer by the insulative layer.

2. The thin film transistor of claim 1, wherein a material of the polymer substrate is selected from the group consisting of polydimethylsiloxane, polyurethane, polyacrylate, polyester, styrene-butadiene rubber, fluorine rubber, and silicone rubber.

3. The thin film transistor of claim 1, wherein the elastic modulus of the polymer substrate is about 1 MPa, 3 MPa, 5 MPa, or 8 MPa.

4. The thin film transistor of claim 1, wherein the carbon nanotubes are selected from the group consisting of single-walled carbon nanotubes, double-walled carbon nanotubes, multi-walled carbon nanotubes, and any combination thereof.

5. The thin film transistor of claim 1, wherein the carbon nanotubes are semi-conductive carbon nanotubes.

6. The thin film transistor of claim 1, wherein a weight percentage of the carbon nanotubes in the semiconductor layer is in a range from about 0.1% to about 1%.

7. The thin film transistor of claim 1, wherein a material of the polymer substrate is polydimethylsiloxane, and the elastic modulus of polydimethylsiloxane is about 500 KPa.

8. The thin film transistor of claim 7, wherein a weight percentage of the carbon nanotubes in the semiconductor layer is about 0.5%.

9. The thin film transistor of claim 1, wherein the insulative layer is located between the gate electrode and the semiconductor layer.

10. The thin film transistor of claim 9, wherein the source electrode and the drain electrode are both located on a surface of the semiconductor layer.

11. The thin film transistor of claim 1, wherein a channel is formed in the semiconductor in a region between the source electrode and the drain electrode, and the gate electrode and the channel are arranged side by side.

12. The thin film transistor of claim 1, wherein the thin film transistor has a top gate structure.

13. The thin film transistor of claim 1, wherein the thin film transistor has a bottom gate structure.

14. A press sensing device, comprising:
a press producing unit generating a pressure; and
a thin film transistor receiving the pressure, and comprising a source electrode, a drain electrode spaced from the source electrode, a semiconductor layer comprising a polymer composite layer and electrically connected with the source electrode and the drain electrode, a gate electrode, and an insulative layer;
wherein the polymer composite layer comprises a polymer substrate and a plurality of carbon nanotubes dispersed in the polymer substrate, an elastic modulus of the polymer substrate ranges from about 0.1 MPa to about 10 MPa, and the gate electrode is electrically insulated from the source electrode, the drain electrode, and the semiconductor layer by the insulative layer.

15. The press sensing device of claim 14, wherein a material of the polymer substrate is selected from the group consisting of polydimethylsiloxane, polyurethane, polyacrylate, polyester, styrene-butadiene rubber, fluorine rubber, and silicone rubber.

16. The press sensing device of claim 14, wherein the elastic modulus of the polymer substrate is about 1 MPa, 3 MPa, 5 MPa, or 8 MPa.

17. The press sensing device of claim 14, wherein the carbon nanotubes are semi-conductive carbon nanotubes.

18. The press sensing device of claim 14, wherein a weight percentage of the carbon nanotubes in the semiconductor layer are in a range from about 0.1% to about 1%.

19. The press sensing device of claim 14, wherein the press producing unit generates pressure from a solid, gas, or liquid.

20. The press sensing device of claim 14, wherein the press producing unit comprises a liquid and a passage receiving the liquid; the pressure and a flowing speed of the liquid can satisfy the following relationship:
$$P + ρ gh + \frac{1}{2} ρ {v}^{2} = Const$$
wherein, P is the pressure generated by the press producing unit, ρ is the density of the liquid, g is gravity acceleration, h is the depth of the liquid in the passage along a pressing direction, v stands for the flowing speed of the liquid; and Const is a constant value.
